(19) United States
(12) Patent Application Publication
(10) Pub. No.: US 2015/0184284 A1
(43) Pub. Date: Jul. 2, 2015

(54) METHOD OF COATING BY PULSED BIPOLAR SPUTTERING

(71) Applicant: OERLIKON ADVANCED TECHNOLOGIES AG, Balzers (LI)

(72) Inventors: Mohamed Elghazzali, Feldkirch (AT); Jürgen Weichart, Balzers (LI)

(73) Assignee: OERLIKON ADVANCED TECHNOLOGIES AG, Balzers (LI)

(21) Appl. No.: 14/410,920

(22) PCT Filed: Jun. 28, 2013
(86) PCT No.: PCT/EP2013/063673

§ 371 Date: Dec. 23, 2014

Related U.S. Application Data
(60) Provisional application No. 61/666,112, filed on Jun. 29, 2012.

(51) Int. Cl. C23C 14/34

(52) U.S. Cl. CPC C23C 14/3485; C23C 14/345; C23C 14/3407

(57) ABSTRACT

A method of pulsed bipolar sputtering including applying a sputtering pulse (−) during a first period of time (T−) and applying a revers voltage pulse during a subsequent second period of time (T+). The step of applying the revers voltage pulse comprises controlling, in particular adjusting, the timing of the revers voltage pulse (T+). This way high quality sputtering is achieved, in particular for sputtering temperature sensitive materials.

### TECHNICAL FIELD OF THE INVENTION

The present invention is related to a method of pulsed bipolar sputtering, an apparatus, a method for manufacturing workpieces and a workpiece.

### BACKGROUND OF THE INVENTION

Pulsed bipolar sputtering is well known in semiconductor manufacturing industry. Such a sputtering is accomplished by applying a negative sputtering pulse and the subsequent positive pulse, which appears as a positive overshoot. This overshoot depends on the chamber impedance and the design of the voltage source, in particular on the fix tapping of the voltage source transformer.

### SUMMARY OF THE INVENTION

The present invention has the objective to propose an improved method of pulsed bipolar sputtering, an improved apparatus, an improved method for manufacturing workpieces and an improved workpiece.

This objective is reached by a method comprising the features specified in claim 1. Further embodiments of the method, an apparatus, a method for manufacturing workpieces and a workpiece are specified in the further claims.

The invention concerns a method of pulsed bipolar sputtering. The method comprises the steps of:
applying a sputtering pulse during a first period of time; and
applying a revers voltage pulse during a subsequent second period of time.

The step of applying the revers voltage pulse comprises controlling, in particular adjusting, the timing of the revers voltage pulse. This way high quality sputtering is achieved, in particular for sputtering temperature sensitive materials.

Throughout this description and the claims the term “pulse” or “applying a pulse” refers to a series of pulses, which may be or may not be periodical in time. Further the term “off-time” refers to a time period between the subsequent sputtering pulses of the same polarity, in particular subsequent negative sputtering pulses. Thus, the revers voltage pulse is applied at least partly during the off-time. The revers voltage pulse may also be applied during the whole off-time.

Surprisingly, the method according to the invention achieves a high quality coating or film by precisely controlling the timing of the revers voltage pulse, in particular its duration and/or intensity. For example, the high quality is achieved by particularly reduced roughness. Further, the method according to the invention provides stable process conditions and an overshooting of the revers voltage, a so called “ringing”, is reduced or avoided. Further, the method according to the invention is particular advantageous for applications with a limited power density, for example for easily evaporable materials such as GST (Ge2Sb2Te5, Germanium Antimony Tellurium).

In an embodiment of the method according to the invention, the controlling is independent of the properties of the sputtering pulse and/or performed according to at least one predetermined value. This way a high level of flexibility and/or a stable voltage is achieved.

In one example, the predetermined value is a substantially constant value, which provides particular stable process conditions during the application of the revers voltage pulse.

In a further embodiment of the method according to the invention, the controlling comprises controlling at least one parameter of the revers voltage pulse, in particular at least one of:
an interval between the first period of time and the second period of time,
a duration of the second period of time,
an interval between the second period of time and the subsequent first period of time,
an off-time, and
an intensity of the pulse, in particular a voltage.

In a further embodiment of the method according to the invention, the controlling is accomplished by operating an H-bridge-circuit.

In a further embodiment of the method according to the invention, the sputtering is an asymmetric pulsed bipolar sputtering, wherein in particular the first period of time is longer or shorter than the second period of time.

In one example, the sputtering pulse is a negative voltage pulse and/or the revers voltage pulse is a positive voltage pulse.

In a further embodiment of the method according to the invention, the interval between the first period of time and the second period of time is at least 1 μs and/or 5 μs or less, in particular 2 μs or less. This way a minimal loss of sputter phase is achieved and attenuation of the discharge is reduced or avoided.

In a further embodiment of the method according to the invention, the method comprises adjusting the second period of time to control film parameters and/or coating properties, in particular roughness, density or stress, further in particular stress of metal layers.

In a further embodiment of the method according to the invention, the method further comprises depositing chalcogenide films, in particular GST, and/or phase change materials, in particular easily evaporable materials.

In a further embodiment of the method according to the invention, the method further comprises forming 3-D structures and/or via filling.

In a further embodiment of the method according to the invention, the sputtering is a low duty cycle sputtering and/or the sputtering pulse is a high power sputtering pulse and the period of time following the second period of time is extended. This way a particular high quality sputtering is achieved, in particular a reduced roughness.

With such a low duty cycle sputtering high power can be applied during the sputtering pulse with a limited pulse length so that critical arcing or evaporation from local heat spots on the target do not occur.

In a further embodiment of the method according to the invention, the method comprises using materials, which have a high vapor pressure and/or are sensitive to the formation of hot spots on the target surface, in particular using GST. This provides the advantage of high ion energies without the risk to form arcs or hot spots.

In a further embodiment of the method according to the invention, the method the method comprises combining the sputtering with a RF bias on a substrate. This way an improved sputtering quality is achieved, in particular a reduced roughness.

Further, the invention concerns an apparatus for bipolar sputtering comprising a sputtering target and a pulse generator for applying a sputtering pulse during a first period of time and a revers voltage pulse during a subsequent second period of time, wherein the pulse generator is configurable, in particular adjustable, to control the reverse voltage pulse.

In a further embodiment of the apparatus according to the invention, the pulse generator comprises an H-bridge-circuit for generating the revers voltage pulse.

Further, the invention concerns a method for manufacturing workpieces by using the method according to any one of the previous method embodiments or the apparatus according to any one of the previous apparatus embodiments, in particular for densification and/or back-sputtering, further in particular for sputtering GST.

Further, the invention concerns a workpiece, which in particular comprises a 3-D structure, further in particular one or more vias, wherein the workpiece is manufactured according to the method of the previous method embodiment.

It is expressly pointed out that any combination of the above-mentioned embodiments, or combinations of combinations, is subject to a further combination. Only those combinations are excluded that would result in a contradiction.

### BRIEF DESCRIPTION OF THE DRAWINGS

Below, the present invention is described in more detail by means of exemplary embodiments and the included simplified drawings. It is shown in:

FIG. 1 an arrangement schematically illustrating the principle of reverse voltage back-sputtering;

FIG. 2 diagrams depicting the principle of high ion energies in bipolar sputtering with a positive overshoot;

FIG. 3 a voltage trace of a DC pulsed power supply with positive overshoot;

FIG. 4 a H bridge-circuit;

FIG. 5 a timing scheme of the asymmetric bipolar pulse;

FIG. 6 a voltage plot of the bipolar pulse;

FIG. 7 high frequency unipolar and bipolar voltage and current plots;

FIG. 8 mid frequency unipolar and bipolar voltage and current plots;

FIG. 9 plots of low duty cycle/high power for low pressure;

FIG. 10 plots of low duty cycle/high power for high pressure; and

FIG. 11 AFM roughness results for bipolar sputtered GST films.

### BRIEF DESCRIPTION OF THE INVENTION

The described embodiments are meant as illustrating examples and shall not confine the invention.

The technical area to which the invention relates

The invention relates to pulsed bipolar sputtering for back-sputtering applications, in particular the filling of vias with materials like phase change, GeSbTe or similar.

### Technical Background

Bipolar sputtering from a single target uses a non-symmetric bipolar pulse where a longer negative pulse is used to sputter the target material and a shorter positive pulse directly after the negative pulse is used in the following applications:

a) extinction of arcs,
b) stress control (see: EP_{—}1511877_B1)

Commercial power supplies, like the Advanced Energy Pinnacle Plus, are designed to meet the expectations of arc extinction in reactive sputtering of insulating layers. These generators use an inductance at the output with a fix tapping. This inductance generates a positive overshoot after the negative sputter pulse to extinguish arcs. The positive overshoot is a part of the off-time of the pulse. The off-time has also been used as a process parameter to adjust film properties, like stress of metal layers, see: EP_{—}1511877_B1. The positive overshoot can also be used for densification or back-sputtering of the substrate.

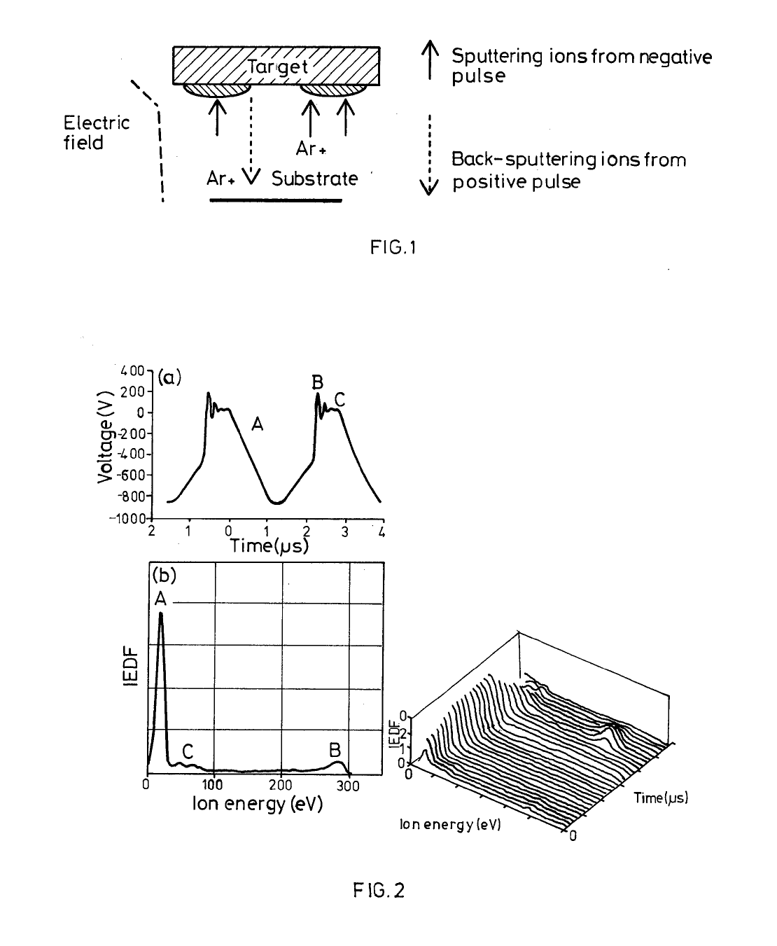

FIG. 1 shows the principle of reverse voltage back-sputtering. During the negative pulse positive ions of the sputter gas (Ar+) are accelerated to the target, while during the positive pulse Ar+ ions are accelerated towards the substrate.

FIG. 2 shows in an upper left diagram a bias waveform applied to the reactor and in a lower left diagram a time-averaged ion energy distribution measured at the substrate holder, where the IEDF axis has a linear scaling. Further, FIG. 2 shows in a right diagram a time resolved ion energy distribution with 100 ns time resolution through the p-dc cycle.

It is remarkable that high ion energies are observed in the positive overshoot, as it has been reported in: Plasma Sources Sci. Technol. 21 (2012) 024004 (see FIG. 2).

Pulsed sputtering has been described to deposit chalcogenide films, like Ge2Sb2Te5 (GST) or similar materials, for phase change materials by pulsed sputtering in the patents EP_{—}1612266_A1 and EP_{—}1710324_B1 as well as in the patent applications US2010/0096255_A1 and US2011/0315543_A1.

### Disadvantages of the Technical Status so Far

The use of the positive overshoot for back-sputtering of the substrate is usually limited due to the fix transformer tapping in the output of the generator. The positive overshoot is a part of the off-time of the pulse. Usually only the off-time can be adjusted in its length and the positive overshoot depends on the generator design—in particular of the output inductance—and the chamber impedance. This means that the positive overshoot phase can usually not be extended by a longer off-time of the generator.

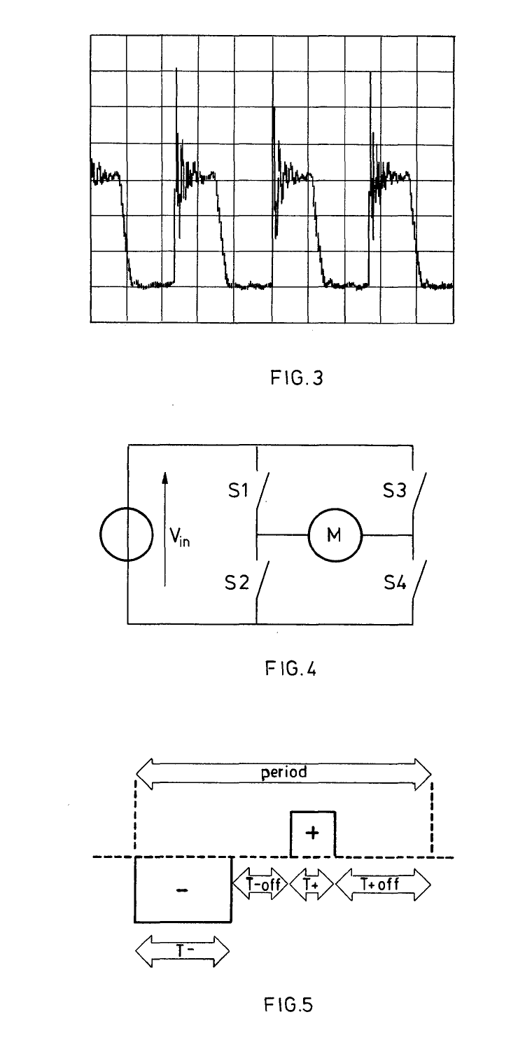

FIG. 3 shows a voltage trace of a DC pulsed power supply with positive overshoot generated by an output inductance running at 150 kHz with 2.6 μs off-time.

Further, FIG. 3 shows the voltage with a typical pulsed power supply working at 150 kHz, 2.6 μs off-time and some positive overshoot, visible as voltage “ringing”. A stable voltage cannot be run with these power supplies.

### Description of the Solution

FIG. 4 shows a H bridge-circuit (from Wikipedia).

A H-bridge-circuit, like depicted in FIG. 4, is used to switch the potential-free output of a DC generator alternating to the magnetron power supply (M). Such a H-bridge-circuit has been described in EP 0534068_B1 for the application in sputter equipment.

FIG. 5 shows a timing scheme of the asymmetric bipolar pulse.

FIG. 5 shows the definition of the pulse times T−on, T−off, T+on and T+off where the sum represents the period time.

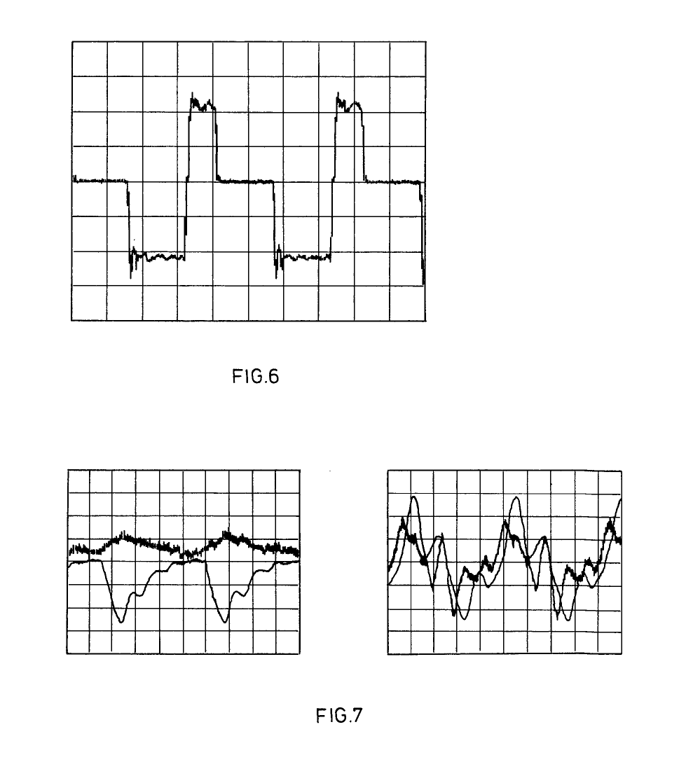

FIG. 6 shows a voltage plot of the bipolar pulse with T−on: 40 μs, T−off: 2 μs, T+on: 20 μs T+off: 40 μs.

The output voltage signal with T−on: 40 μs, T−off: 2 μs, T+on: 20 μs T+off: 40 μs is plotted in FIG. 6. T−on represents the sputter pulse. T−off should be as short as possible, like 5 μs, 2 μs or even less. This is important to get a minimal loss of ions from the sputter phase T−on and to avoid attenuation of the discharge.

T+on is the essential parameter to adjust the back-sputtering and the film properties. An independent voltage may be used, however this is not possible with the H-bridge-circuit, which is a very practical and useful approach. T+off can be as short as possible, but it can also be used to decrease the duty cycle for reasons described below. The timing is written like (40/2/20/40) in the case of FIG. 6.

FIG. 7 shows high frequency (100 kHz) unipolar and bipolar voltage and current plots, the left plot shows an unipolar pulse 4/6 μs and the right plot a bipolar pulse 4/2/2/2 μs.

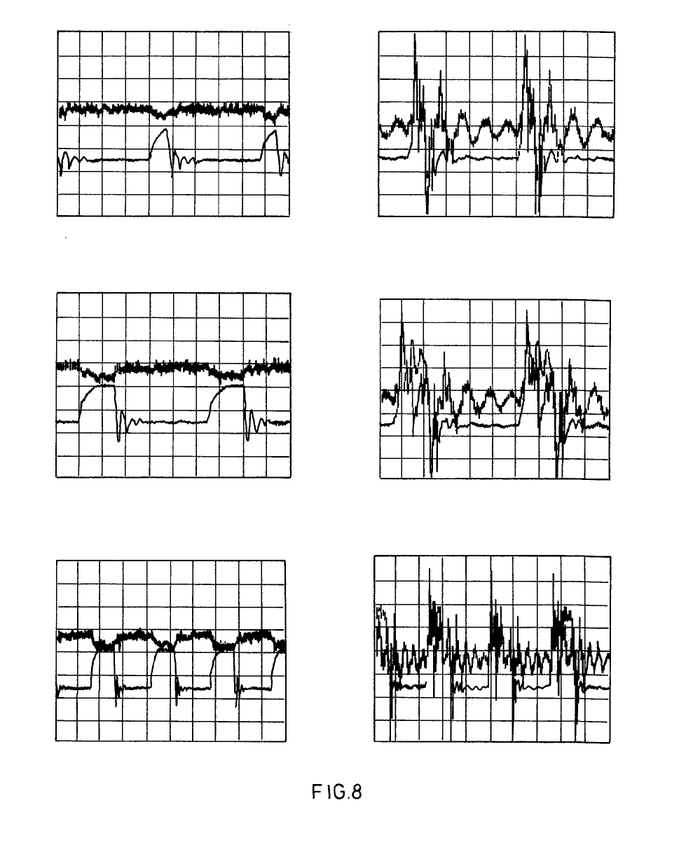

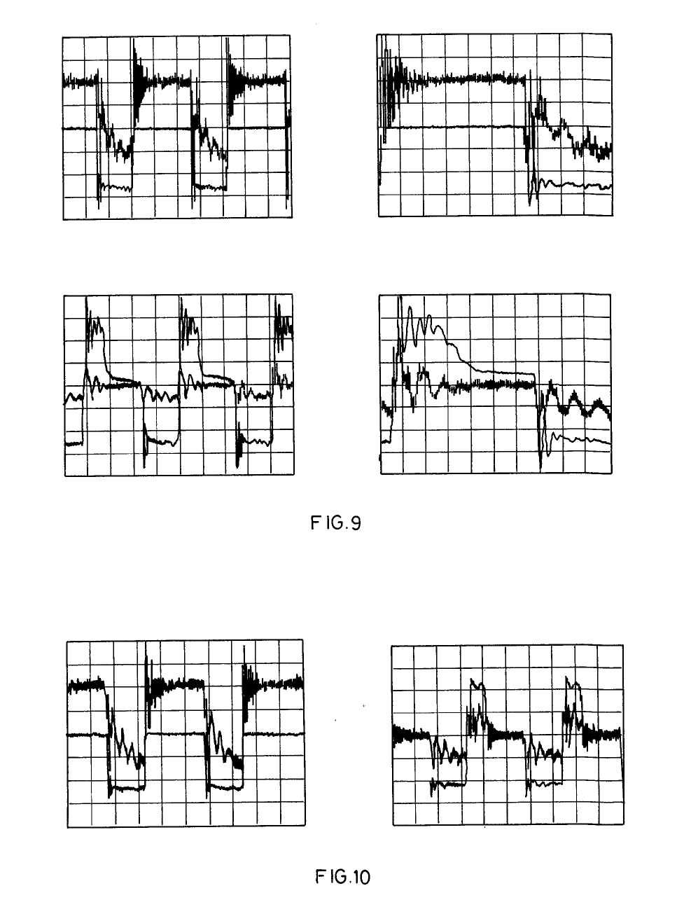

FIG. 8 shows mid frequency unipolar and bipolar voltage and current plots, in particular:

the upper left plot an unipolar pulse 40/6 μs,
the upper right plot a bipolar pulse 40/2/2/2 μs,
the middle left plot an unipolar pulse 40/14 μs,
the middle right plot a bipolar pulse 40/2/10/2 μs,
the lower left plot an unipolar pulse 40/24 μs, and
the lower right plot a bipolar pulse 40/2/20/2 μs.

Voltage and current traces for sputtering of GST from a round target with 300 mm diameter at a low power of 200 Watt are compared between unipolar and bipolar mode in FIG. 7 and FIG. 8 for different frequencies and duty cycles. In both figures T−on and the frequency are kept the same for the unipolar (left) and the bi-polar case (right). FIG. 7 shows the unipolar (T−on/T−off) and bipolar voltage traces (T−on/T−off/T+on/T+off) for high frequency (100 kHz) with the same duty cycle and frequency.

In FIG. 8 T−on is 40 μs and T+on is varied from 2 to 10 and 20 μs. For the unipolar case T−off is set to the sum of T−off, T+on and T+off in order to run with the same duty cycle.

In application the length of the positive pulse is used to adjust the back-sputtering rate of the substrate during deposition. The following table 1 shows the deposition rates of GST from a round target with 300 mm diameter running at 200 Watt and the rate reduction of bipolar vs unipolar sputtering with T−off and T+off being both at 2 μs. The back-sputtering is for example used to keep the edges of a via open during filling.

TABLE 1

| | | | | | | | | rate reduction | |
|---|---|---|---|---|---|---|---|---|---|
| | | | | deposition rate GST in nm/s | | | | bipolar vs unipolar | |
| pulse times | | | | UNIPOLAR, | UNIPOLAR, | BIPOLAR, | BIPOLAR, | T + on | |
| T − on | T + on | duty cycle | | T + on 40 μs | T + on 4 μs | T + on 40 μs | T + on 4 μs | 40 μs | T + on 4 μs |
| 40 | 2 | 87% | | 1.5 | | 1.2 | | 84% | |
| 40 | 10 | 74% | | 1.5 | | 1.2 | | 80% | |
| 40 | 20 | 63% | | 1.4 | | 1.1 | | 74% | |
| 4 | 2 | | 40% | | 1 | | 0.4 | | 38% |

Table 1 shows the deposition rates of GST and the rate reduction of bipolar vs unipolar sputtering.

The sputtering of easily evaporable materials like GST is usually limited to a certain power density since —depending on the quality of the target material —evaporation from hot spots may occur, which may lead to arcing, the formation of particles or even damage of the target surface. In the case of a round target with 300 mm diameter with an average material quality this limit may already be reached at 400 Watt for GST.

Bipolar sputtering with independently adjustable pulse times provides a significant advantage for easily evaporable materials, like GST, since it allows sputtering at a low duty cycle. By this a high power can be run in the sputter pulse and limited in the pulse length T−on so that critical arcing or evaporation from local heat spots on the target do not occur within the sputter pulse T−on.

FIG. 9 shows plots of low duty cycle/high power for low pressure, in particular:

the upper left plot a low duty cycle/high power for low pressure unipolar pulse 40/62 μs,
the upper right plot a detail,
the lower left plot a low duty cycle/high power for low pressure bipolar pulse 40/2/20/40 μs, and
the lower right plot a detail.

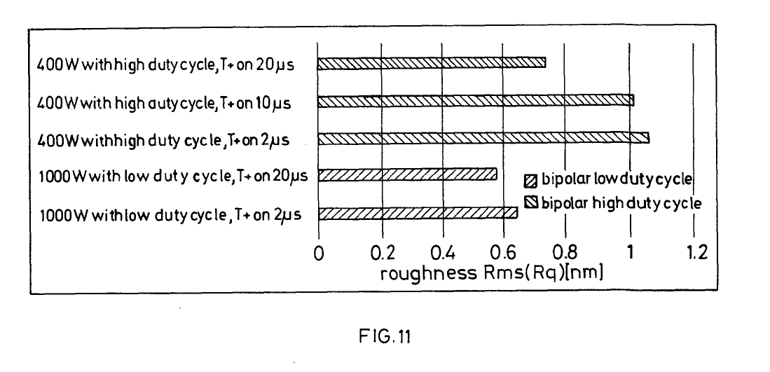

FIG. 10 shows plots of low duty cycle/high power for high pressure, the left plot a low duty cycle/high power for high pressure unipolar pulse 40/62 μs and the right plot a low duty cycle/high power for high pressure bipolar pulse 40/2/20/40 μs.

Voltage and current traces for unipolar as well as bipolar sputtering GST with high power and low duty cycle are plotted in FIG. 9 for low pressure and in FIG. 10 for high pressure. In the details of FIG. 9 it can be seen that current peaks run up to 8 A in the negative pulse and even up to 10 A in the positive pulse. The average current however is only 1.2 A in the negative pulse and 0.1 A in the positive pulse.

The adjustable reverse voltage pulse length T+on is used to adjust film parameters, like stress, roughness, density or via filling. A typical indicator for the densification by back-sputtering is the roughness as measured by Atomic Force Microscopy (AFM).

FIG. 11 shows AFM roughness results for bipolar sputtered 200 nm GST films comparing processes with high power low duty cycle and low power high duty cycle and different reverse voltage pulse lengths.

The roughness Rms (Rq) by AFM has been measured for GST films of 200 nm thickness for different processes as plotted in FIG. 11:
i) Bipolar with lower power of 400 W and high duty cycle, T−on 40 μs, T+on 2 μs, 10 μs and 20 μs
ii) Bipolar with higher power of 1000 W and low duty cycle, T−on 40 μs, T+on 2 μs and 20 μs

The results clearly show that:
Enhanced reverse pulse reduces the roughness
Higher power and lower duty cycle reduces the roughness

Further results show that:
Lower pressure reduces the roughness
The addition of RF bias on the substrate reduces the roughness

The reverse voltage pulse is able to replace RF back-sputtering of the substrate in particular for via filling. However it is an advantage to combine the bipolar sputtering with RF bias on the substrate.

What should be protected?
a) Asymmetric bipolar sputtering with adjustable reverse voltage
b) A setup for bipolar sputtering using a H-bridge-circuit
c) Using the adjustable reverse voltage pulse length T+on to adjust film parameters, like stress, roughness, density or via filling.
d) Using the adjustable reverse voltage pulse length to enable via filling with GST.
e) Bipolar sputtering with high power in the pulse but low duty cycle, resp. extended T+off.
f) Application of low duty cycle bipolar sputtering for materials having a high vapor pressure and therefore being sensitive to the formation of hot spots on the target surface, like GST, with the advantage of providing high ion energies without the risk to form arcs or hot spots.
g) Application of low duty cycle bipolar sputtering for via filling with GST.
h) Combination of the bipolar sputtering with RF bias on the substrate.

1. Method of pulsed bipolar sputtering, the method
comprising the steps of:
applying a sputtering pulse (−) during a first period of time (T−); and
applying a revers voltage pulse during a subsequent second period of time (T+),
wherein the step of applying the revers voltage pulse comprises controlling, in particular adjusting, the timing of the revers voltage pulse (T+).

2. The method according to claim 1, wherein the controlling is independent of the properties of the sputtering pulse and/or performed according to at least one predetermined value.

3. The method according to claim 1, wherein the controlling comprises controlling at least one parameter of the revers voltage pulse (+), in particular at least one of:
an interval (T−off) between the first period of time (T−) and the second period of time (T+),
a duration of the second period of time (T+),
an interval (T+off) between the second period of time (T+) and the subsequent first period of time
(T−),
an off-time (Toff), and
an intensity of the pulse, in particular a voltage.

4. The method according to claim 1, wherein the controlling is accomplished by operating an H-bridge-circuit.

5. The method according to claim 1, wherein the sputtering is an asymmetric pulsed bipolar sputtering, wherein in particular the first period of time (T−) is longer or shorter than the second period of time (T+).

6. The method according to claim 1, wherein the interval (T−off) between the first period of time (T−) and the second period of time (T+) is at least 1 μs and/or 5 μs or less, in particular 2 us or less.

7. The method according claim 1, wherein the method comprises adjusting the second period of time (T+) to control film parameters and/or coating properties, in particular roughness, density or stress, further in particular stress of metal layers.

8. The method according to claim 1, wherein the method further comprises depositing chalcogenide films, in particular GST, and/or phase change materials, in particular easily evaporable materials.

9. The method according to claim 1, wherein the method further comprises forming 3-D structures and/or via filling.

10. The method according to claim 1, wherein the sputtering is a low duty cycle sputtering and/or the sputtering pulse (−) is a high power sputtering pulse (−) and the period of time (T+off) following the second period of time (T+) is extended.

11. The method according to claim 10, wherein the method comprises using materials having a high vapor pressure and/or being sensitive to the formation of hot spots on the target surface, in particular using GST.

12. The method according to claim 1, wherein the method comprises combining the sputtering with a RF bias on a substrate.

13. An apparatus for bipolar sputtering comprising a sputtering target and a pulse generator for applying a sputtering pulse (−) during a first period of time (T−) and a revers voltage pulse (+) during a subsequent second period of time (T+), wherein the pulse generator is configurable, in particular adjustable, to control the reverse voltage pulse (+).

14. The apparatus according to claim 13, wherein the pulse generator comprises an H-bridge-circuit for generating the revers voltage pulse (+).

15. A method for manufacturing workpieces by using the method according to claim 13, in particular for densification and/or back-sputtering, further in particular for sputtering GST.

16. A workpiece, which in particular comprises a 3-D structure, further in particular one or more vias, wherein the workpiece is manufactured according to claim 13.
